(19) United States
(12) Patent Application Publication
(10) Pub. No.: US 2025/0087492 A1
(43) Pub. Date: Mar. 13, 2025

(54) PROCESSING METHOD

(71) Applicant: DISCO CORPORATION, Tokyo (JP)

(72) Inventors: Tomoaki SUGIYAMA, Tokyo (JP); Atsushi KUBO, Tokyo (JP)

(21) Appl. No.: 18/823,105

(22) Filed: Sep. 3, 2024

(30) Foreign Application Priority Data
Sep. 12, 2023 (JP) 2023-147446

(51) Int. Cl. H01L 21/304; B24B 7/22

(52) U.S. Cl. CPC H01L 21/3043; B24B 7/228

(57) ABSTRACT

A processing method is for thinning a wafer formed with a chamfered portion on an outer periphery, and includes: forming an annular groove from the first surface side of the wafer along an outer peripheral edge of the wafer to a predetermined thickness and forming a remaining portion below the annular groove, the annular groove being formed so that a distance between a groove bottom and the second surface side of the wafer decreases from a center side of the wafer toward the outer peripheral edge side and a position of the groove bottom in a thickness direction of the wafer varies in a width direction; and bringing a grinding stone into contact with the second surface and moving the grinding stone in the thickness direction to grind the second surface side while crushing and removing the remaining portion, so as to thin the wafer to the predetermined thickness.

### CROSS-REFERENCE TO RELATED APPLICATION

The present application claims priority to and incorporates by reference the entire contents of Japanese Patent Application No. 2023-147446 filed in Japan on Sep. 12, 2023.

### BACKGROUND

The present disclosure relates to a processing method for a wafer having a chamfered portion formed on an outer periphery.

In order to prevent edge chipping when a semiconductor wafer is ground by a grinding device, so-called edge trimming for trimming a chamfered portion of the semiconductor wafer is widely performed.

However, when the wafer subjected to the edge trimming is ground by the grinding device, the outer peripheral portion of the trimmed wafer is broken, and the arc scrap falls from the wafer. Then, there is a problem that the scrap is accumulated in a drain port in a processing chamber called a water case of the grinding device, and the discharge of the processing water is hindered.

Therefore, a processing device including a mechanism capable of suppressing generation of a scrap by crushing the scrap has been proposed (see, for example, JP 2021-109278 A).

However, it is earnestly desired that generation of a scrap can be suppressed without using a processing device having a special mechanism.

### SUMMARY

A processing method according to one aspect of the present disclosure is for thinning a wafer having a first surface and a second surface opposite to the first surface and formed with a chamfered portion on an outer periphery to a predetermined thickness by grinding the second surface, and includes: forming an annular groove from the first surface side of the wafer along an outer peripheral edge of the wafer to the predetermined thickness and forming a remaining portion below the annular groove, the annular groove being formed so that a distance between a groove bottom and the second surface side decreases from a center side of the wafer toward the outer peripheral edge side of the wafer and a position of the groove bottom in a thickness direction of the wafer varies in a width direction; and after forming the annular groove and the remaining portion is performed, bringing a grinding stone into contact with the second surface of the wafer and moving the grinding stone in the thickness direction of the wafer to grind the second surface side of the wafer while crushing and removing the remaining portion, so as to thin the wafer to the predetermined thickness.

### BRIEF DESCRIPTION OF THE DRAWINGS

FIG. 1 is a perspective view illustrating an example of a wafer to be processed by a processing method according to a first embodiment;

FIG. 2 is a cross-sectional view taken along line II-II in FIG. 1;

FIG. 3 is a flowchart illustrating a flow of a processing method according to the first embodiment;

FIG. 4 is a cross-sectional view schematically illustrating an annular groove forming step of the processing method illustrated in FIG. 3;

FIG. 5 is a cross-sectional view of an outer edge portion of a cutting blade illustrated in FIG. 4;

FIG. 6 is a cross-sectional view schematically illustrating a wafer after a front surface protection step in the processing method illustrated in FIG. 3;

FIG. 7 is a side view schematically illustrating, in a partial cross section, a state immediately after the start of grinding in a grinding step of the processing method illustrated in FIG. 3;

FIG. 8 is an enlarged side view schematically illustrating a partial cross section of a portion VIII illustrated in FIG. 7;

FIG. 9 is a side view schematically illustrating, in a partial cross section, a state in which a remaining portion is ground in the grinding step of the processing method illustrated in FIG. 3;

FIG. 10 is a side view schematically illustrating, in a partial cross section, a state in which the wafer is ground to a predetermined thickness in the grinding step of the processing method illustrated in FIG. 3;

FIG. 11 is a cross-sectional view schematically illustrating a state in which a first annular groove is formed in an annular groove forming step of the processing method according to a second embodiment;

FIG. 12 is a cross-sectional view schematically illustrating a state in which a second annular groove is formed in the annular groove forming step of the processing method according to the second embodiment;

FIG. 13 is a cross-sectional view schematically illustrating a state in which a third annular groove is formed in the annular groove forming step of the processing method according to the second embodiment;

FIG. 14 is a cross-sectional view schematically illustrating a wafer or the like on which an annular groove is formed in the annular groove forming step of the processing method according to the second embodiment;

FIG. 15 is a side view schematically illustrating, in a partial cross section, a grinding step of the processing method according to the second embodiment; and

FIG. 16 is a cross-sectional view schematically illustrating an annular groove forming step in a processing method according to a third embodiment.

### DETAILED DESCRIPTION

Modes (embodiments) for carrying out the present disclosure will be described in detail with reference to the drawings. The present invention is not limited by contents described in the following embodiments. In addition, constituent elements described below include those that can be easily assumed by those skilled in the art and those that are substantially the same. Furthermore, configurations described below can be appropriately combined. In addition, various omissions, substitutions, or changes in the configuration can be made without departing from the gist of the present invention.

### First Embodiment

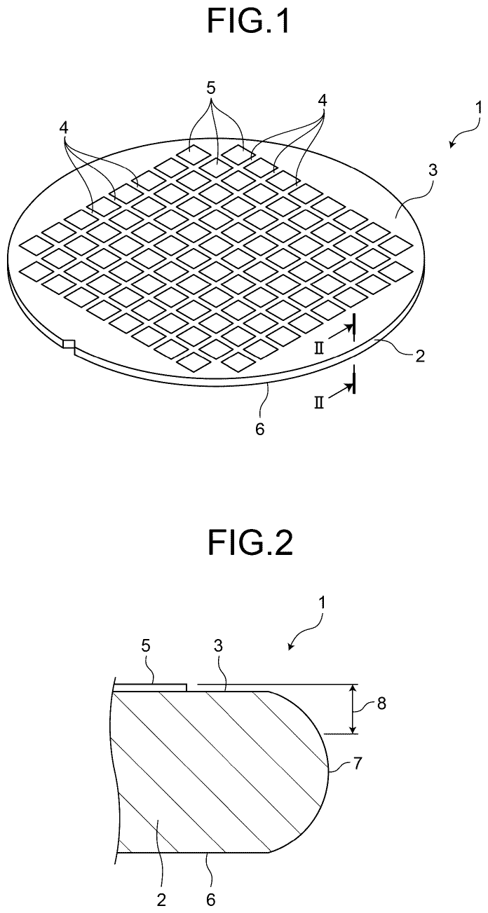

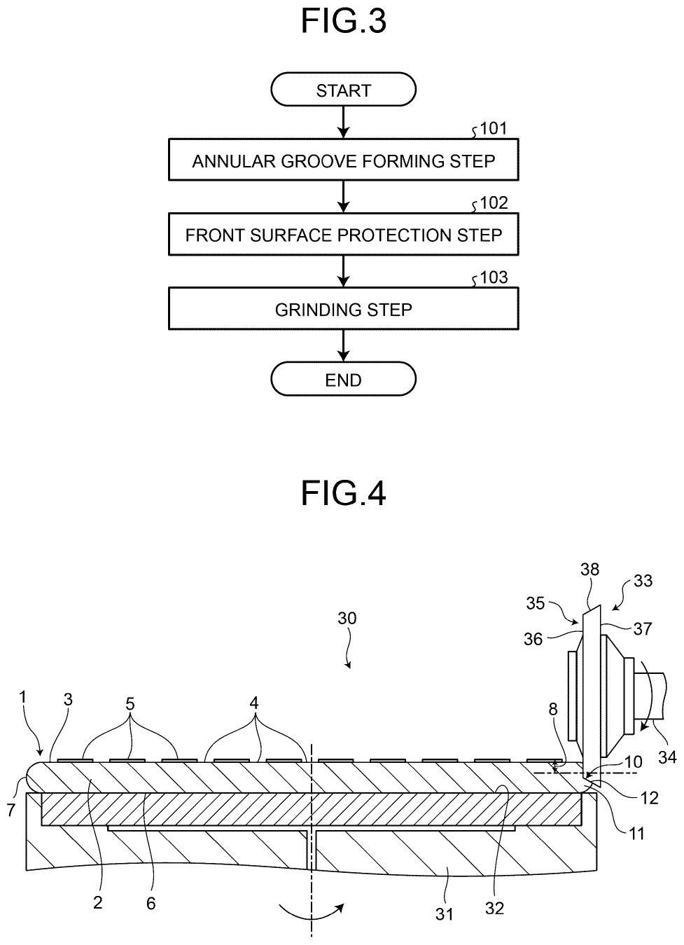

A processing method according to a first embodiment of the present invention will be described with reference to the drawings. FIG. 1 is a perspective view illustrating an example of a wafer to be processed by the processing method according to the first embodiment. FIG. 2 is a cross-sectional view taken along line II-II in FIG. 1. FIG. 3 is a flowchart illustrating a flow of a processing method according to the first embodiment.

### Workpiece

The processing method according to the first embodiment is a method of thinning a wafer 1 illustrated in FIG. 1. The wafer 1 to be processed in the processing method of the first embodiment is, for example, a disk-shaped semiconductor wafer having a silicon substrate 2, a front surface 3 (corresponding to a first surface), and a back surface 6 (corresponding to a second surface) opposite to the front surface 3. In the present disclosure, the wafer 1 is not limited to silicon, but may be a disk-shaped semiconductor wafer or optical device wafer having a substrate 2 made of gallium arsenide, sapphire, SiC, lithium tantalate, lithium niobate, or the like.

In the wafer 1, as illustrated in FIG. 1, a plurality of lines to divide 4 crossing each other are set on the front surface 3 of the substrate 2, and a device 5 is formed in a region defined by the lines to divide 4 on the front surface 3 of the substrate 2.

The device 5 is, for example, an integrated circuit such as an integrated circuit (IC) or a large scale integration (LSI), an image sensor such as a charge coupled device (CCD) or a complementary metal oxide semiconductor (CMOS), an optical element such as a light-emitting diode (LED), or a memory (semiconductor storage device).

In addition, as illustrated in FIG. 2, a chamfered portion 7 is formed on the outer periphery of the wafer 1. The chamfered portion 7 is formed from the front surface 3 to the back surface 6, and is formed in an arcuate cross section such that the center in the thickness direction is located on the outermost peripheral side. The wafer 1 is thinned to a predetermined thickness 8 by grinding the back surface 6 side or the like after the outer peripheral edge is removed to a depth exceeding the predetermined thickness 8 over the entire circumference from the front surface 3 side. The wafer 1 is then divided into individual devices 5 along the lines to divide 4.

### Processing Method

The processing method according to the first embodiment is a method of grinding the back surface 6 of the wafer 1 to reduce a thickness to the predetermined thickness 8. As illustrated in FIG. 3, the processing method according to the first embodiment includes an annular groove forming step 101, a front surface protection step 102, and a grinding step 103.

### Annular Groove Forming Step

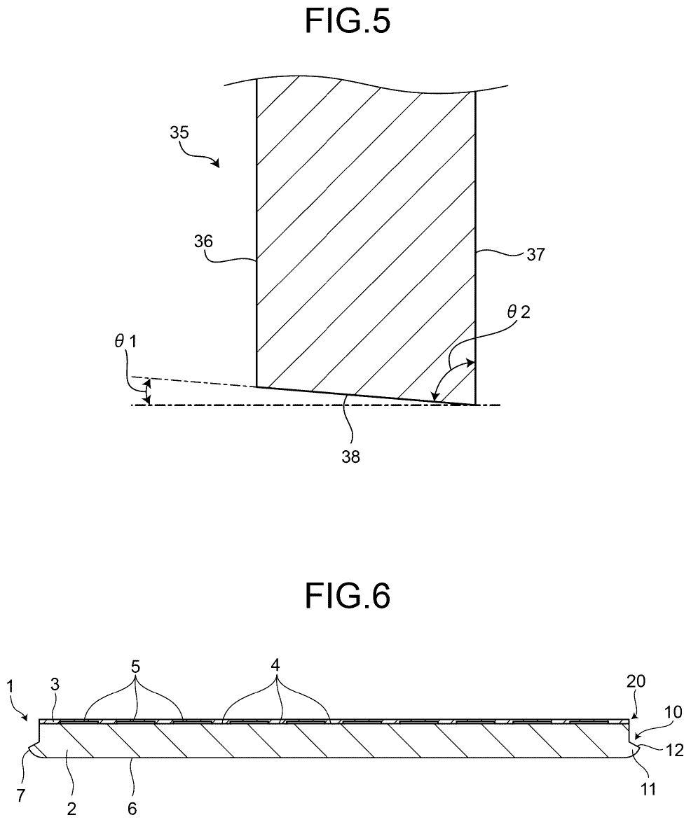

FIG. 4 is a cross-sectional view schematically illustrating the annular groove forming step of the processing method illustrated in FIG. 3. FIG. 5 is a cross-sectional view of an outer edge portion of a cutting blade illustrated in FIG. 4. The annular groove forming step 101 is a step of forming an annular groove 10 reaching the predetermined thickness 8 from the front surface 3 side of the wafer 1 along the outer peripheral edge of the wafer 1 and forming a remaining portion 11 below the annular groove 10.

In the first embodiment, in the annular groove forming step 101, a cutting device 30 illustrated in FIG. 4 suction-holds the back surface 9 side of the wafer 1 on a holding surface 32 of a chuck table 31. In the first embodiment, in the annular groove forming step 101, the cutting device 30 rotates a cutting blade 35 about the axis by a spindle 34, positions the lower end of the cutting blade 35 above the outer peripheral edge of the wafer 1, and then lowers a cutting unit 33.

In the first embodiment, in the annular groove forming step 101, as illustrated in FIG. 4, the cutting device 30 causes the cutting blade 35 to cut an outer peripheral edge of the wafer 1 to a depth exceeding a predetermined thickness 8, and rotates the chuck table 31 about an axis. In the first embodiment, in the annular groove forming step 101, the cutting device 30 removes the chamfered portion 7 of the wafer 1 in an annular shape from the front surface 3 side to form an annular groove 10 coaxial with the wafer 1 around the entire circumference of the wafer 1 with a depth exceeding the predetermined thickness 8 along the outer peripheral edge, and also forms the remaining portion 11 below the annular groove 10 on the back surface 6 side.

In the first embodiment, in the annular groove forming step 101, the outer peripheral edge of the wafer 1 is cut over the entire circumference with a ring-shaped cutting blade 35 having a flat first surface 36 perpendicular to the axis and a flat second surface 37 located on the opposite side of the first surface 36, parallel to the first surface 36, and further on the outer peripheral side of the wafer 1 than the first surface 36, to remove the chamfered portion 7 over the entire circumference from the front surface 3 side. In addition, in the first embodiment, the cutting blade 35 that cuts the wafer 1 in the annular groove forming step 101 is set so that the diameter on the second surface 37 side is larger than the diameter on the first surface 36 side, and as illustrated in FIG. 5, in a cross section passing through the axis, the cross section of an outer peripheral surface 38, which is the tip, is inclined with respect to the axis of the cutting blade 35 in a direction in which the outer diameter increases toward the second surface 37, forming a single-sided V-shape.

In addition, in the first embodiment, the cutting blade 35 that cuts the wafer 1 in the annular groove forming step 101 is formed so that, in a cross section passing through the axis, an angle θ1 (hereinafter referred to as an inclination angle) of the outer peripheral surface 38 relative to the axis is 4 degrees or more and 9 degrees or less, and an angle θ2 (hereinafter referred to as a tip angle) of the outer peripheral surface 38 relative to the second surface 37 is 81 degrees or more and 86 degrees or less. In addition, in the first embodiment, the cutting blade 35 that cuts the wafer 1 in the annular groove forming step 101 cuts into the wafer 1 by positioning the second surface 37 on the outer peripheral side further than the outer peripheral edge of the wafer 1 from above, and then lower the first surface 36 deeper than the predetermined thickness 8.

For this reason, in the first embodiment, the annular groove 10 formed in the annular groove forming step 101 is formed so that a distance between a groove bottom 12 and the back surface 6 decreases from a center side of the wafer 1 toward an outer peripheral edge side of the wafer 1 and a position of the groove bottom 12 in a thickness direction of the wafer 1 varies in a width direction. That is, the annular groove 10 is inclined with respect to the horizontal direction (That is, both the front surface 3 and the back surface 6) so that the groove bottom 12 gradually approaches the back surface 6 from the center side toward the outer peripheral edge of the wafer 1.

Thus, in the first embodiment, in the annular groove forming step 101, the cutting device 30 lowers the cutting blade 35 positioned above the chamfered portion 7 of the wafer 1, causing the cutting blade 35 to cut into a position including the outer peripheral edge of the wafer 1, and the wafer 1 is rotated around its axis on the chuck table 31 in a so-called chopper cut, thereby performing a so-called edge trimming to remove the outer peripheral edge of the wafer 1 from the front surface 3 side, thereby forming the annular groove 10. However, in the present disclosure, the annular groove forming step 101 may be performed by the cutting device 30 moving the cutting blade 35, a lower end of which is positioned below the front surface 3 by a predetermined thickness 8, horizontally relative to the wafer 1 to cut into the wafer 1, and rotating the wafer 1 about the axis on the chuck table 31 to perform edge trimming of removing the outer peripheral edge of the wafer 1 from the front surface 3, thereby forming the annular groove 10.

### Front Surface Protection Step

FIG. 6 is a cross-sectional view schematically illustrating a wafer after a front surface protection step in the processing method illustrated in FIG. 3. A front surface protection step 102 is a step of arranging a tape 20 as a protective member on the front surface 3 of the wafer 1.

In the first embodiment, in the front surface protection step 102, as illustrated in FIG. 6, the tape 20 having the same diameter as the wafer 1 is attached to the front surface 3 of the wafer 1. In the first embodiment, the tape 20 is used as the protective member, but in the present disclosure, the protective member is not limited to the tape 20.

In addition, in the first embodiment, the tape 20 is an adhesive tape including a base layer made of a non-adhesive and flexible resin, and an adhesive layer laminated on the base layer and made of an adhesive and flexible resin, the adhesive layer being attached to the front surface 3 of the wafer 1. Further, in the present disclosure, the tape 20 may be a sheet that does not have an adhesive layer, is made of only a base material made of a thermoplastic resin, and is bonded to the front surface 3 of the wafer 1 by being heated.

### Grinding Step

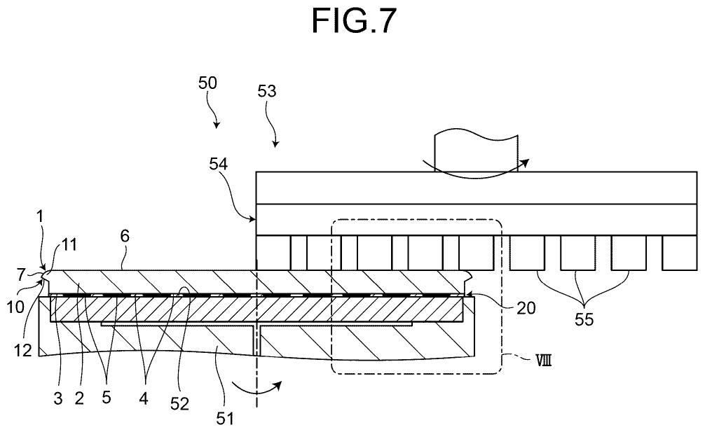

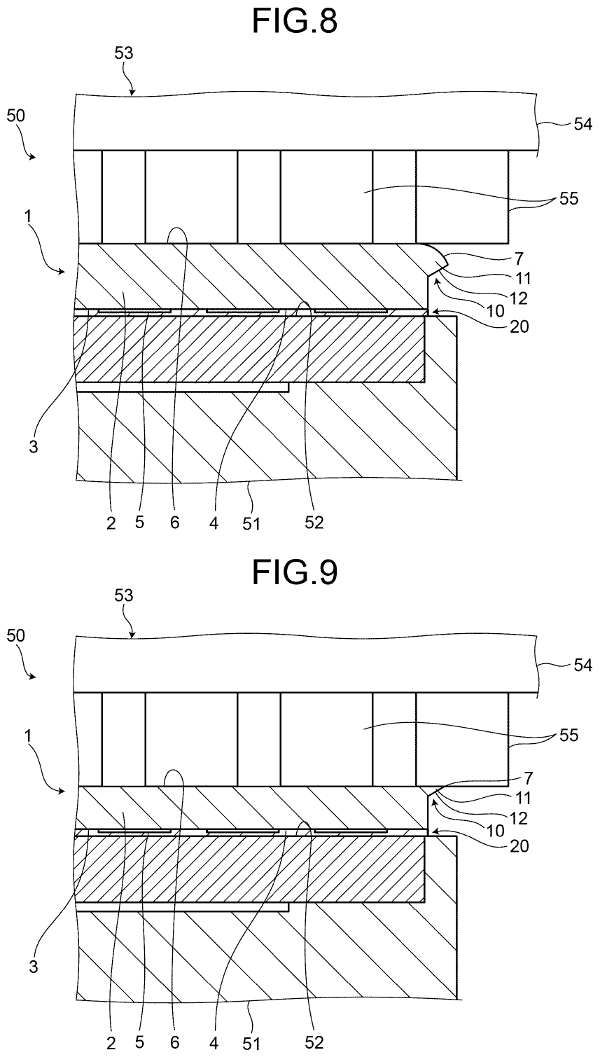

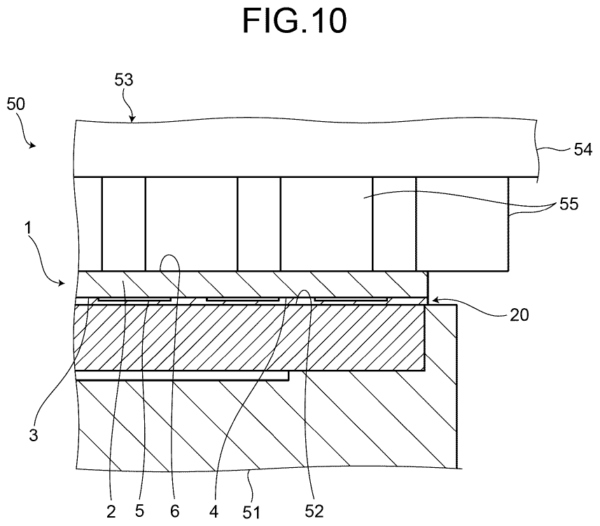

FIG. 7 is a side view schematically illustrating, in a partial cross section, a state immediately after the start of grinding in a grinding step of the processing method illustrated in FIG. 3. FIG. 8 is an enlarged side view schematically illustrating a partial cross section of a portion VIII illustrated in FIG. 7. FIG. 9 is a side view schematically illustrating, in a partial cross section, a state in which the remaining portion is ground in the grinding step of the processing method illustrated in FIG. 3. FIG. 10 is a side view schematically illustrating, in a partial cross section, a state in which the wafer is ground to a predetermined thickness in the grinding step of the processing method illustrated in FIG. 3.

The grinding step 103 is a step in which, after the annular groove forming step 101, a grinding stone 55 is brought into contact with the back surface 6 of the wafer 1 and the grinding stone 55 is moved in the thickness direction of the wafer 1 to grind the back surface 6 side of the wafer 1 while crushing and removing the remaining portion 11, thereby thinning the wafer 1 to the predetermined thickness 8. In the first embodiment, in the grinding step 103, a grinding device 50 suction-holds the front surface 3 side of the wafer 1 on a holding surface 52 of the holding table 51 via the tape 20.

In the first embodiment, in the grinding step 103, as illustrated in FIGS. 7 and 8, the grinding device 50 rotates the holding table 51 around an axis parallel to the vertical direction while rotating a grinding wheel 54 of a grinding unit 53 around an axis parallel to the vertical direction, so that the grinding stone 55 of the grinding wheel 54 comes into contact with the back surface 6 of the wafer 1, and the grinding unit 53 is fed toward the front surface 3 of the wafer 1 to grind the back surface 6 side with the grinding stone 55. Then, as illustrated in FIG. 9, the grinding device 50 gradually grinds the remaining portion 11 with the grinding stone 55.

In the first embodiment, in the grinding step 103, since the groove bottom 12 of the annular groove 10 is inclined in a direction gradually approaching the back surface 6 toward the outer peripheral edge, the grinding stone 55 gradually grinds and removes the remaining portion 11 from the outer peripheral side toward the center of the wafer 1. In the first embodiment, in the grinding step 103, as illustrated in FIG. 10, the grinding device 50 thins the wafer 1 to the predetermined thickness 8, and when the wafer 1 is thinned to the predetermined thickness 8, the processing method ends. Then, since the annular groove 10 is formed from the front surface 3 to a depth exceeding the predetermined thickness 8, the remaining portion 11, that is, the entire chamfered portion 7 is removed from the outer peripheral edge of the wafer 1.

In the processing method according to the first embodiment described above, in the annular groove forming step 101, the annular groove 10 is formed in which the distance between the groove bottom 12 and the back surface 6 decreases from the center side of the wafer 1 toward the outer peripheral edge side and the position of the groove bottom 12 in the thickness direction of the wafer 1 varies in the width direction. For this reason, in the processing method according to the first embodiment, the remaining portion 11 is gradually removed from the outer peripheral side toward the center of the wafer 1 in the grinding step 103. Therefore, the processing method according to the first embodiment can suppress the possibility of generation of a scrap after processing.

As a result, the processing method of the first embodiment merely forms the annular groove 10 in which the groove bottom 12 gradually approaches the back surface 6 as it moves toward the outer peripheral edge, thereby achieving the effect of suppressing the generation of scrap material without using a processing device with a special mechanism.

### Second Embodiment

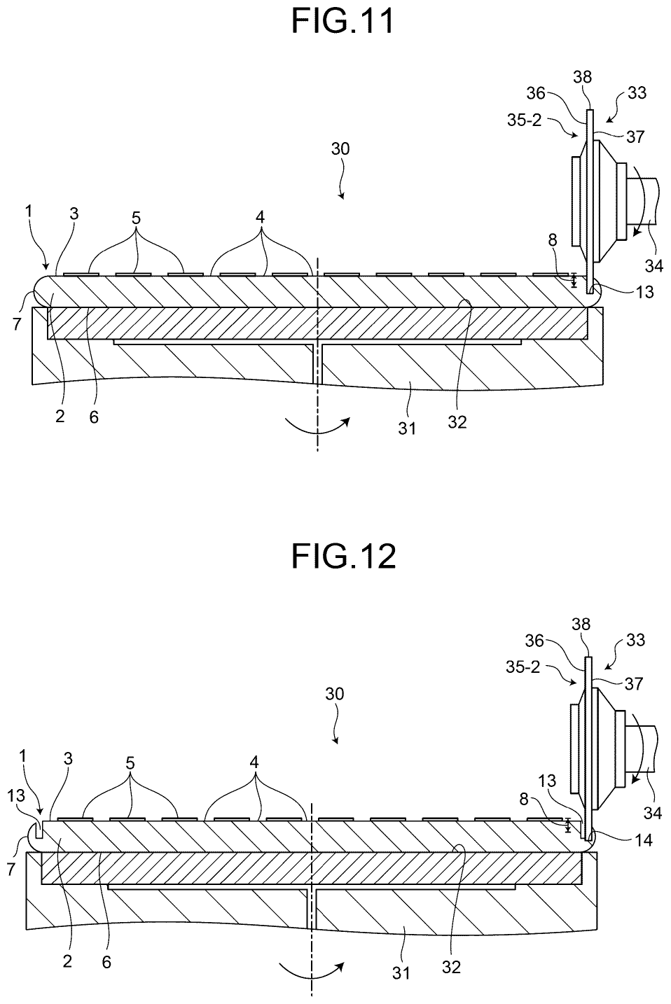

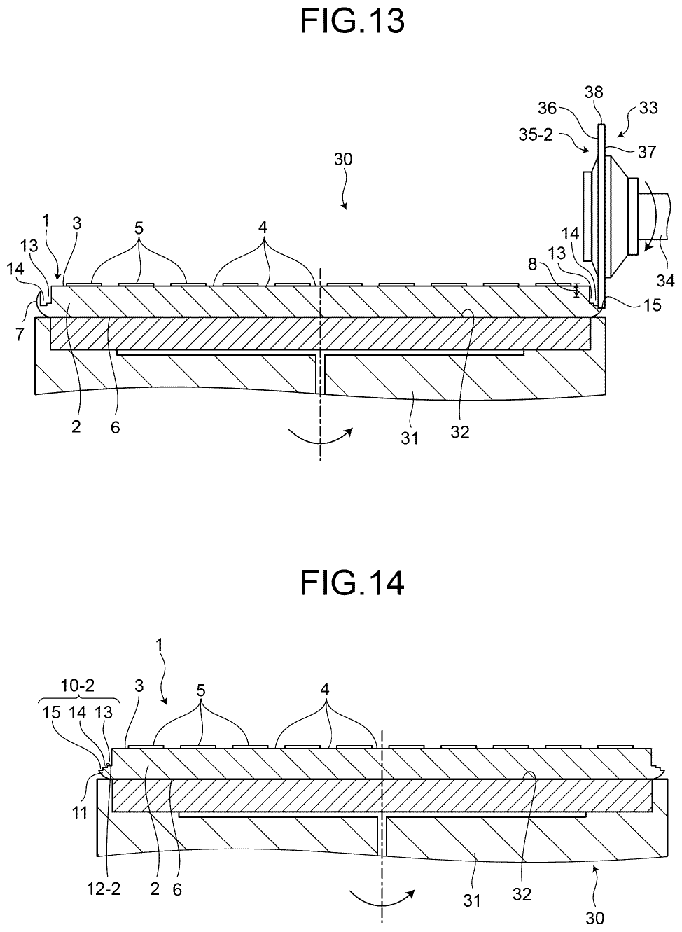

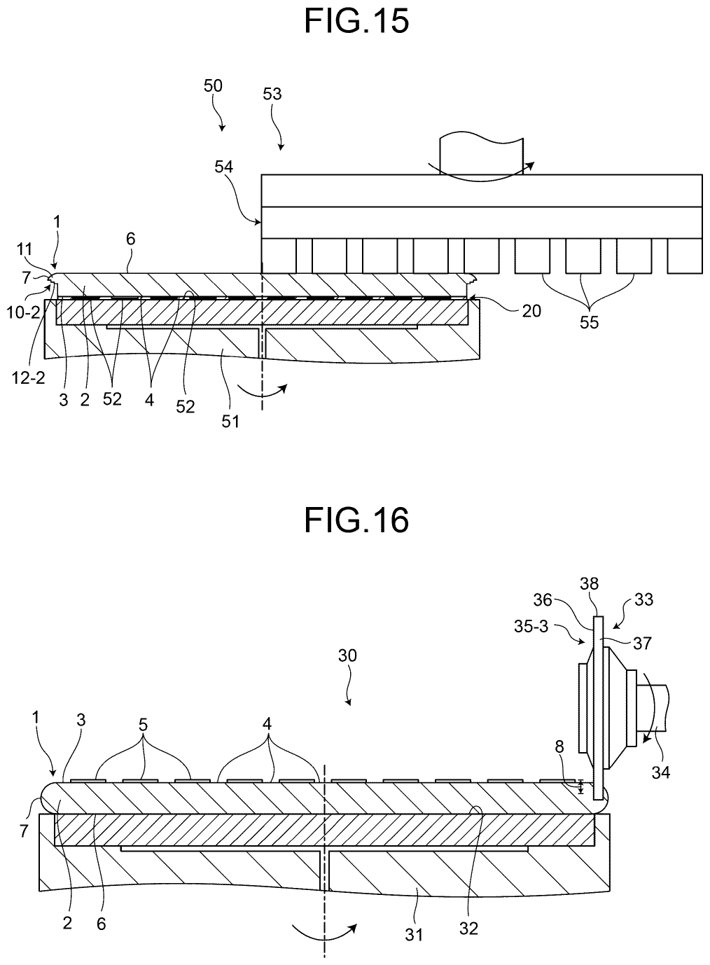

A processing method according to a second embodiment will be described with reference to the drawings. FIG. 11 is a cross-sectional view schematically illustrating a state in which a first annular groove is formed in an annular groove forming step of the processing method according to the second embodiment. FIG. 12 is a cross-sectional view schematically illustrating a state in which a second annular groove is formed in the annular groove forming step of the processing method according to the second embodiment. FIG. 13 is a cross-sectional view schematically illustrating a state in which a third annular groove is formed in the annular groove forming step of the processing method according to the second embodiment. FIG. 14 is a cross-sectional view schematically illustrating a wafer or the like on which an annular groove is formed in the annular groove forming step of the processing method according to the second embodiment. FIG. 15 is a side view schematically illustrating, in a partial cross section, a grinding step of the processing method according to the second embodiment. In FIGS. 11, 12, 13, 14, and 15, the same parts as those in first embodiment are denoted by the same reference numerals, and description thereof is omitted.

The processing method according to the second embodiment is the same as that of the first embodiment except that the annular groove forming step 101 is different. In the second embodiment, in the annular groove forming step 101, in the cross section passing through the axis, an outer peripheral surface 38 of a cutting blade 35-2 that cuts the outer peripheral edge of the wafer 1 of the cutting device 30 is flat along the axis. In the second embodiment, in the annular groove forming step 101, the cutting device 30 suction-holds the back surface 6 of the wafer 1 on the holding surface 32 of the chuck table 31, and then positions a second surface 37 of the cutting blade 35-2 more inward than the outer peripheral edge of the wafer 1. Then, the cutting blade 35-2 cuts into the wafer 1 to a depth exceeding the predetermined thickness 8, to form a first annular groove 13 coaxial with the wafer 1 around the entire circumference of the wafer 1 to a depth exceeding the predetermined thickness 8 along the outer peripheral edge of the wafer 1, as illustrated in FIG. 11.

In the second embodiment, in the annular groove forming step 101, after the cutting device 30 forms the first annular groove 13 in the wafer 1, the cutting blade 35-2 is positioned further on the outer peripheral side of the wafer 1 than when the first annular groove 13 was formed, and the cutting blade 35-2 is caused to cut deeper into the wafer 1 than when the first annular groove 13 was formed, to form a second annular groove 14 over the entire circumference of the wafer 1 along the outer peripheral edge of the wafer 1 to a depth exceeding a predetermined thickness 8, as illustrated in FIG. 12, which is coaxial with the wafer 1 and communicates with the first annular groove 13. In the second embodiment, in the annular groove forming step 101, after the cutting device 30 forms the second annular groove 14 in the wafer 1, the cutting blade 35-2 is positioned further on the outer peripheral side of the wafer 1 than when the second annular groove 14 was formed, and the cutting blade 35-2 is caused to cut deeper into the wafer 1 than when the second annular groove 14 was formed, to form a third annular groove 15 along the outer peripheral edge of the wafer 1 to a depth exceeding the predetermined thickness 8, as illustrated in FIG. 13, which is coaxial with the wafer 1 and communicates with the annular grooves 13 and 14, around the entire circumference of the wafer 1.

Thus, in the second embodiment, in the annular groove forming step 101, the cutting device 30 removes the chamfered portion 7 of the wafer 1 in an annular shape from the front surface 3 side, as illustrated in FIG. 14, to form an annular groove 10-2 around the entire circumference of the wafer 1, the annular groove 10-2 being composed of the annular grooves 13, 14, and 15 that are coaxial with the wafer 1 and communicate with each other to the depth exceeding the predetermined thickness 8 along the outer peripheral edge, and also forms a remaining portion 11 below the annular groove 10-2 on the back surface 6 side. As described above, in the second embodiment, in the annular groove forming step 101, the cutting device 30 cuts the wafer 1 a plurality of times with the cutting blade 35-2, and cuts different positions in the width direction of the annular groove 10-2 with different cutting depths with the cutting blade 35-2 to form the stepped annular groove 10 in which the distance between a groove bottom 12-2 and the back surface 6 decreases from the center side of the wafer 1 toward an outer peripheral edge side of the wafer 1.

In the second embodiment, in the annular groove forming step 101, the cutting device 30 forms the three annular grooves 13, 14, and 15 to form the annular groove 10-2. However, in the present disclosure, at least two annular grooves 13, 14, and 15 may be formed to form the annular groove 10-2. In the second embodiment, the cutting blade 35-2 may have a blade thickness thinner than the width of the annular groove 10-2 to be formed, the same blade thickness, or a thicker blade thickness.

In the second embodiment, in the grinding step 103, the grinding device 50 holds the front surface 3 side of the wafer 1 on the holding surface 52 of the holding table 51 via the tape 20, and grinds the back surface 6 to thin the wafer 1 to the predetermined thickness 8 as illustrated in FIG. 15.

In the processing method of the second embodiment, in the annular groove forming step 101, the annular groove 10-2 is formed in which the distance between the groove bottom 12-2 and the back surface 6 decreases from the center side of the wafer 1 toward the outer peripheral edge side and the position of the groove bottom 12-2 in the thickness direction of the wafer 1 varies in the width direction. As a result, in the processing method according to the second embodiment, in the grinding step 103, the remaining portion 11 is gradually removed from the outer peripheral side toward the center of the wafer 1, and similarly to the first embodiment, the annular groove 10-2 is formed in which the groove bottom 12-2 gradually approaches the back surface 6 as it moves toward the outer peripheral edge, thereby achieving the effect of suppressing the generation of scrap material without using a processing device with a special mechanism.

### Third Embodiment

A processing method according to a third embodiment will be described with reference to the drawings. FIG. 16 is a cross-sectional view schematically illustrating an annular groove forming step in the processing method according to the third embodiment. In FIG. 16, the same parts as those in the first embodiment are denoted by the same reference numerals and the description thereof will be omitted.

The processing method according to the third embodiment is the same as that of the first embodiment except that the annular groove forming step 101 is different. In the third embodiment, in the annular groove forming step 101, in the cross section passing through the axis, an outer peripheral surface 38 of a cutting blade 35-3 that cuts the outer peripheral edge of the wafer 1 of the cutting device 30 is flat along the axis. In the third embodiment, in the annular groove forming step 101, the cutting device 30 suction-holds the back surface 6 of the wafer 1 on the holding surface 32 of the chuck table 31, then positions a second surface 37 of the cutting blade 35-3 more inward than the outer peripheral edge of the wafer 1, and then causes the cutting blade 35-3 to cut into the wafer 1 to a depth exceeding a predetermined thickness 8. As illustrated in FIG. 16, the chuck table 31 is rotated around its axis while the cutting blade 35-3 is moved closer to the back surface 6 side and toward the outer periphery of the wafer 1, thereby forming an annular groove 10 having a shape equivalent to that of the first embodiment.

In the processing method of the third embodiment, in the annular groove forming step 101, the annular groove 10 is formed in which the distance between the groove bottom 12 and the back surface 6 decreases from the center side of the wafer 1 toward the outer peripheral edge side and the position of the groove bottom 12 in the thickness direction of the wafer 1 varies in the width direction. As a result, in the processing method according to the third embodiment, in the grinding step 103, the remaining portion 11 is gradually removed from the outer peripheral side toward the center of the wafer 1, and similarly to the first embodiment, the annular groove 10 is formed in which the groove bottom 12 gradually approaches the back surface 6 as it moves toward the outer peripheral edge, thereby achieving the effect of suppressing the generation of scrap material without using a processing device with a special mechanism.

Next, the inventors confirmed the effect of the processing method according to the first embodiment. The results are shown in Table 1 below. In the confirmation, annular grooves 10 were formed on the outer peripheral edge of the wafer 1 using cutting blades 35 of Comparative Example 1, Comparative Example 2, Comparative Example 3, Comparative Example 4, Comparative Example 5, Present Invention Product 1, Present Invention Product 2, Present Invention Product 3, Present Invention Product 4, Present Invention Product 5 and Present Invention Product 6, and the falling of scrap and chipping after processing when the grinding step 103 was performed were confirmed.

In Table 1, when scraps fell during or after the grinding step 103, the scraps' falling status is marked with a cross, and when scraps did not fall during or after the grinding step 103, the scraps' falling status is marked with a circle. In addition, in Table 1, the chipping status of chips after processing in which the number and size of chippings are a specified number or less is marked with a circle, and the chipping status of chips after processing in which the number and size of chippings exceed a specified number is marked with an X.

TABLE 1

| | Inclination | | Scrap Dropping | Chipping |
|---|---|---|---|---|
| | Angle | | Status | Status |
| Comparative | 0 | degrees | x | ∘ |
| Example 1 | | | | |
| Comparative | 1 | degree | x | ∘ |
| Example 2 | | | | |
| Comparative | 2 | degrees | x | ∘ |
| Example 3 | | | | |
| Comparative | 3 | degrees | x | ∘ |
| Example 4 | | | | |
| Present Invention | 4 | degrees | ∘ | ∘ |
| Product 1 | | | | |
| Present Invention | 5 | degrees | ∘ | ∘ |
| Product 2 | | | | |
| Present Invention | 6 | degrees | ∘ | ∘ |
| Product 3 | | | | |
| Present Invention | 7 | degrees | ∘ | ∘ |
| Product 4 | | | | |
| Present Invention | 8 | degrees | ∘ | ∘ |
| Product 5 | | | | |
| Present Invention | 9 | degrees | ∘ | ∘ |
| Product 6 | | | | |
| Comparative | 10 | degrees | ∘ | x |
| Example 5 | | | | |

In Comparative Example 1, the annular groove 10 was formed by the cutting blade 35 having the inclination angle θ1 of 0 degrees. In Comparative Example 2, the annular groove 10 was formed by the cutting blade 35 having the inclination angle θ1 of 1 degree. In Comparative Example 3, the annular groove 10 was formed by the cutting blade 35 having the inclination angle θ1 of 2 degrees. In Comparative Example 4, the depth of cutting in the annular groove forming step 101 was increased, and the annular groove 10 was formed by the cutting blade 35 having the oblique angle θ1 of 3 degrees. In Comparative Example 5, the annular groove 10 was formed by the cutting blade 35 having the inclination angle θ1 of 10 degrees.

In Present Invention Product 1, the annular groove 10 was formed by the cutting blade 35 having the inclination angle θ1 of 4 degrees. In Present Invention Product 2, the annular groove 10 was formed by the cutting blade 35 having the inclination angle θ1 of 5 degrees. In Present Invention Product 3, the annular groove 10 was formed by the cutting blade 35 having the inclination angle θ1 of 6 degrees. In Present Invention Product 4, the annular groove 10 was formed by the cutting blade 35 having the inclination angle θ1 of 7 degrees. In Present Invention Product 5, the annular groove 10 was formed by the cutting blade 35 having the inclination angle θ1 of 8 degrees. In Present Invention Product 6, the annular groove 10 was formed by the cutting blade 35 having the inclination angle θ1 of 9 degrees.

According to Table 1, in Comparative Example 1, Comparative Example 2, Comparative Example 3, and Comparative Example 4, the scraps dropped during the grinding step 103 or after the grinding step 103. In Comparative Example 5, the depth of cutting in the annular groove forming step 101 increased, and the number and size of chipping after processing exceeded a predetermined number.

In contrast to Comparative Example 1, Comparative Example 2, Comparative Example 3, Comparative Example 4, and Comparative Example 5 described above, in Present Invention Product 1, Present Invention Product 2, Present Invention Product 3, Present Invention Product 4, Present Invention Product 5, and Present Invention Product 6, there was no drop of the scraps during the grinding step 103 or after the grinding step 103, and the number and size of chipping after processing were a predetermined number or less.

Therefore, according to Table 1, it has become clear that, by forming the annular groove 10 with the cutting blade 35 having the inclination angle θ1 of 1 degree or more and 9 degrees or less, it is possible to suppress generation of a scrap without using a processing device of a special mechanism while suppressing chipping after processing.

According to the present disclosure, it is possible to suppress generation of scraps without using a processing device with a special mechanism.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A processing method for thinning a wafer having a first surface and a second surface opposite to the first surface and formed with a chamfered portion on an outer periphery to a predetermined thickness by grinding the second surface, the processing method comprising:
forming an annular groove from the first surface side of the wafer along an outer peripheral edge of the wafer to the predetermined thickness and forming a remaining portion below the annular groove, the annular groove being formed so that a distance between a groove bottom and the second surface side decreases from a center side of the wafer toward the outer peripheral edge side of the wafer and a position of the groove bottom in a thickness direction of the wafer varies in a width direction; and
after forming the annular groove and the remaining portion is performed, bringing a grinding stone into contact with the second surface of the wafer and moving the grinding stone in the thickness direction of the wafer to grind the second surface side of the wafer while crushing and removing the remaining portion, so as to thin the wafer to the predetermined thickness.

2. The processing method according to claim 1, wherein forming the annular groove and the remaining portion includes cutting the wafer with a cutting blade having a tip cross section of a single-sided V-shape, the cutting blade having a first surface and a second surface opposite to the first surface, a diameter on the second surface side being set to a value larger than a diameter on the first surface side.

3. The processing method according to claim 1, wherein forming the annular groove and the remaining portion includes cutting the wafer with a cutting blade at different positions in a width direction of the annular groove at different cutting depths.
